(19) United States
(12) Patent Application Publication
(10) Pub. No.: US 2026/0171331 A1
(43) Pub. Date: Jun. 18, 2026

(54) INSERT FOR A METER BOX

(71) Applicant: ABB Schweiz AG, Baden (CH)

(72) Inventors: Jean-Michel Pelletier, Saint-Jean Sur Richelieu (CA); Daniel Lalancette, Saint-Jean Sur Richelieu (CA); Yves Boucher, Saint-Jean Sur Richelieu (CA); Alexandre Santerre, Saint-Jean Sur Richelieu (CA)

(21) Appl. No.: 18/981,212

(22) Filed: Dec. 13, 2024

(51) Int. Cl. H01H 9/00; H02G 3/08; G01R 21/00

(52) U.S. Cl. CPC H01H 9/00; H02G 3/08; G01R 21/007

(57) ABSTRACT

Provided is an insert for actuating a bypass mechanism in a meter box. The insert comprises a unitary body that further comprises a head, the head further comprising a bore, the bore being configured to receive a tool for applying a torque to the insert to enable or disable the meter box bypass mechanism. The unitary body further comprises a hub that defines an interior, the hub having a wall terminating at a hub end, the hub and body extending along a central axis, the hub further comprising a base located in the interior and a plurality of breakline grooves extending through the hub, each of the plurality of grooves extending in a direction aligned with the central axis from a location along the hub proximate the head to a location along the hub proximate the base.

### TECHNICAL FIELD

The present disclosure generally relates to meter boxes that include inserts for enabling meter box bypass mechanisms, and in particular to inserts for meter boxes where the inserts prevent damage to the bypass mechanism components when an operating torque that exceeds an acceptable threshold is applied to the insert.

### BACKGROUND

In electrical installations for residential or commercial buildings, meter boxes act as the point of connection between the building electrical system and the larger electrical grid. Electrical inputs from the electrical grid are connected to a meter socket, which in turn is connected to the building’s electrical system. A meter box is connected to the meter socket and measures power consumption in the building where the meter box is installed. The meter box forms a circuit with the electrical grid and the electrical system of the building, wherein during normal operation current flows through the meter socket via the meter.

For high-amperage electrical systems, it is often desirable for the meter socket to include a bypass mechanism. During use, the bypass mechanism serves to create a low-resistance electrical pathway which does not include the meter. As a result, the meter can safely be disconnected from the meter socket, as current is diverted through the low resistance pathway. Without such a bypass mechanism, arc flashing may be produced as the meter is separated from the meter socket. Known bypass systems typically include an internal gear mechanism which physically completes the bypass circuit. The gear mechanism may include a number of meshed gears. In some housings, the internal gear mechanism is actuated by an insert.

Known bypass mechanisms often includes a fail-safe mechanism which prevents unintentional deactivation of the bypass circuit. When it is necessary to remove or install a meter, the bypass mechanism is unlocked, enabling the use of the bypass mechanism. The fail safe mechanism of the system bypass ensures that the bypass circuit is not opened unintentionally. An unintentional opening of the circuit before the meter is installed or removed from a meter box can produce undesirable arc flashing.

An example of such a bypass mechanism fail-safe mechanism is a plunger-based bypass locking system. In the plunger-based locking system, the meter socket includes a plurality of plungers which lock the bypass mechanism in place when there is no meter installed in the meter box. When a meter is installed, the plungers are repositioned and as a result, the previously locked bypass mechanism is unlocked, thereby disconnecting the meter socket from the bypass circuit. In known meter box designs that include the plunger-based bypass locking system, the cables used to connect the meter box to the electrical grid or building electrical system can interfere with the plunger system, preventing the plungers from effectively locking the bypass mechanism.

Actuating the meter box bypass mechanism can cause the mechanism component parts to be damaged and can produce an open circuit. In particular, when actuating bypass mechanisms, users may have difficulty moving or otherwise repositioning the bypass mechanism. In such instances the users apply an excessive actuating force to the bypass mechanism. The excessive force or torque can damage the gear train components. The damage may render the bypass mechanism inoperable, or may be of such a degree that the meter box would need to be replaced in its entirety. Repairing the damaged components or meter box is expensive. Additionally, poor cable management within the meter box can result in unintentional circumvention of the bypass mechanism.

Accordingly, there exists a need to cure the deficiencies of the current bypass mechanism designs for a meter boxes. Specifically, there is a need to provide a bypass mechanism that includes a device, system and method that prevents the application of forces to the bypass mechanism that are likely to damage the meter box components including the associated meter box bypass mechanism. These and other needs are met by the improved bypass mechanism discussed herein.

This section is intended to introduce the reader to various aspects of art that may be related to various aspects of the present disclosure described or claimed below. This description is believed to be helpful in providing the reader with background information to facilitate a better understanding of the various aspects of the present disclosure. Accordingly, it should be understood that these statements are to be read in this light and not as admissions of prior art.

### BRIEF DESCRIPTION

Provided is an insert for actuating a bypass mechanism in a meter box. The insert comprises a unitary body that further comprises a head, the head further comprising a bore, the bore being configured to receive a tool for applying a torque to the insert to enable or disable the meter box bypass mechanism. The unitary body further comprises a hub that defines an interior, the hub having a wall terminating at a hub end, the hub and body extending along a central axis, the hub further comprising a base located in the interior and a plurality of breakline grooves extending through the hub, each of the plurality of grooves extending in a direction aligned with the central axis from a location along the hub proximate the head to a location along the hub proximate the base.

Further disclosed is an insert for actuating a bypass mechanism in a meter box, the insert comprising: a unitary body further comprising a head, the head further comprising a bore, the bore being configured to receive a tool for applying a torque to the insert to enable or disable the meter box bypass mechanism, the head comprising a radially extending channel that extends through the head; and a hub that defines an interior, the hub having a wall terminating at a hub end, the hub and body extending along a central axis, the hub further comprising an opening extending through the hub wall, the opening being in communication with the channel, the hub further comprising a base located in the interior, and a plurality of breakline grooves extending through the hub, each of the plurality of grooves having a closed end, an open end, and laterally opposed breakline groove walls extending between the open and closed ends, the breakline grooves extending in a direction aligned with the central axis, the closed end being located proximate the head and the open end located proximate the base.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated examples may be incorporated into any of the above-described aspects, alone or in any combination.

### BRIEF DESCRIPTION OF DRAWINGS

The following drawings form part of the present specification and are included to further demonstrate certain aspects of the present disclosure. The disclosure may be better understood by reference to one or more of these drawings in combination with the detailed description of specific embodiments presented herein.

FIG. 1 is a perspective view of a meter box that includes a bypass mechanism;

FIG. 2 is a front view of the meter box of FIG. 1 with the front meter box cover removed;

FIG. 3A is a front view of the bypass mechanism, according to an embodiment;

FIG. 3B is a perspective view of the bypass mechanism of FIG. 3A;

FIG. 4 is a perspective view of an insert for use with the bypass mechanism of FIG. 3A and 3B;

FIG. 5 is a side view of the insert of FIG. 4 that shows a breakline groove provided in the insert;

FIGS. 6A-6C are a series of cross-section views of the breakline groove, taken along respective section lines 6A-6A, 6B-6B, and 6C-6C shown in in FIG. 5;

FIG. 7 is a detailed view of the portion of insert enclosed by the detail identified as detail 7 in FIG. 5;

FIG. 8 is a top view of the insert;

FIG. 9 is a bottom view of the insert;

FIG. 10 is a view of the insert after undergoing a fracture;

FIG. 11 is a flow chart outlining a method for moving the insert ; and

FIG. 12 is a magnified view of a portion of a base of the meter box of FIG. 2 enclosed in the area identified as 12 in FIG. 2.

Corresponding reference characters indicate corresponding parts throughout the several views of the drawings. Although specific features of various examples may be shown in some drawings and not in others, this is for convenience only. Any feature of any drawing may be referenced or claimed in combination with any feature of any other drawing.

### DETAILED DESCRIPTION

The following detailed description and examples set forth preferred materials, components, and procedures used in accordance with the present disclosure. This description and these examples, however, are provided by way of illustration only, and nothing therein shall be deemed to be a limitation upon the overall scope of the present disclosure. The following terms are used in the present disclosure as defined below.

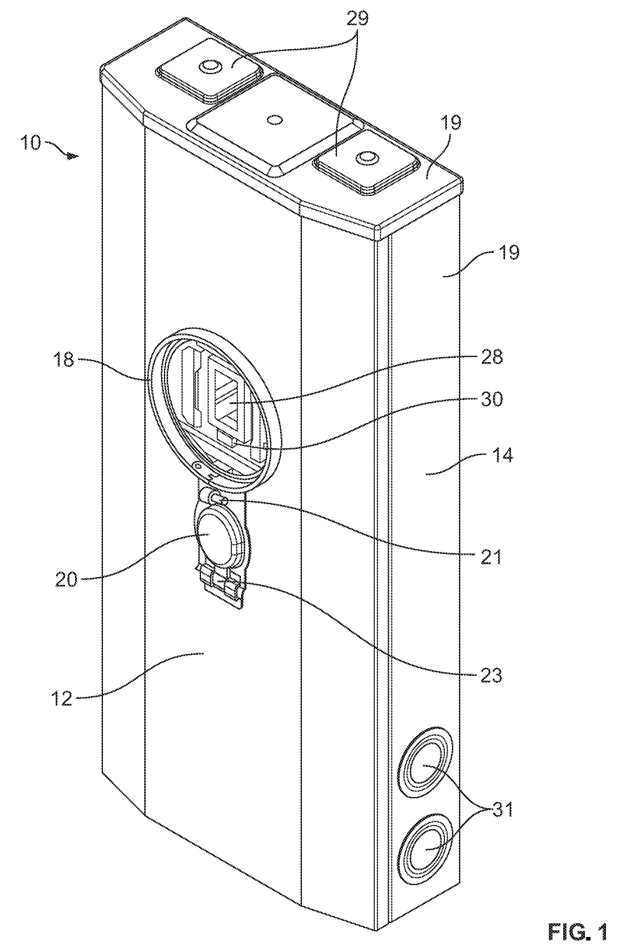

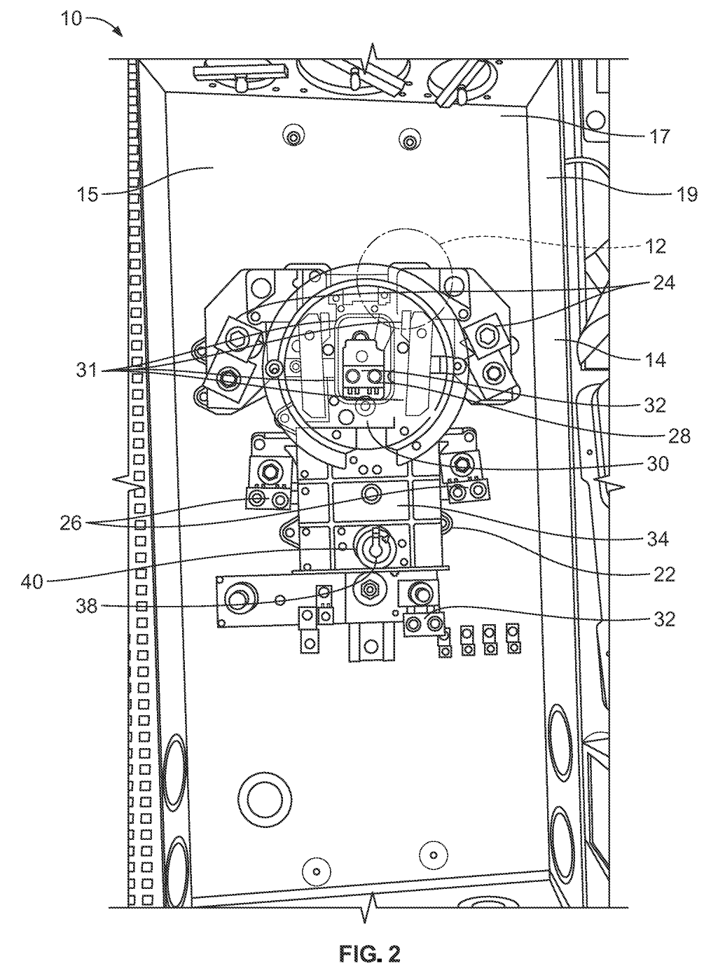

Meter box 10 is shown in FIG. 1. The meter box 10 is configured to be installed on an outer surface of a building and serves to measure power usage of the associated building. A meter (not shown) in FIG. 1 provides an indication of the power used by the associated building. The meter box is adapted to receive power delivery cables (not shown) that are connected to the meter box at service feed electrical contacts 24 of the meter box 10 (see FIG. 2). Additional cables (not shown) that deliver the received power to the building are connected to building electrical contacts 26 of the meter box 10 (see FIG. 2). The power delivery cables (not shown) are connected to a breaker box or main breaker panel for the building or other structure where the meter box is used. Neutral contacts 32 are provided within the meter box 10 to complete the power delivery circuit.

As shown in FIG. 1, the meter box 10 includes a housing 14 that is closed by a cover 12. The cover 12 is removably attached to the housing. The cover may be movable relative to the housing 14 by hinges or other known means (not shown). The housing comprises floor 17 and walls 19 that define a housing chamber 15. The cover 12 closes the housing chamber 15. The cover includes an opening 18, which is configured such that the meter (not shown) protrudes through the opening 18 when connected to the meter box socket 28. The socket is shown in the view of the meter box 10 shown in FIG. 2 with the cover 12 removed. Portal 20 is separately provided in the cover 12. The portal 20 is movable relative to the cover toward and away from the cover by a hinge connection 23. The portal 20 may be locked in place as shown in FIG. 1 using a conventional locking mechanism 21 such as a padlock. When the portal is unlocked, the portal 20 may be moved away from the cover and thereby provide limited access to components within the meter box housing chamber 15 without the need to fully remove the cover 12 from the housing 14. In particular, the portal 20 allows access to components which actuate a meter box bypass mechanism 36, which will be described in detail below. The meter box components, described in detail herein, are located in the chamber 15. The housing 14 combined with the cover 12 serve to fully protect the components located in the housing chamber 15 when the meter box 10 is mounted for use on an associated building. The housing 14 and cover 12 may have substantially rectangular profile shapes and configurations. The housing and cover may comprise any profile configuration or shape that may be attached to a building for use, and enclose and protect the meter box components.

FIG. 2 shows a front view of the meter box 10 with the meter box cover 12 removed. The plurality of discrete meter box components are located in the housing chamber 15. The meter box may be attached to a building at the base 22. Electrical power supply lines (not shown) are connected to the meter box 10 at service feed electrical contacts 24. The main power supply lines may be located in the housing chamber 15 through openings 29 provided in wall 19 and shown in FIG. 1. Building power supply lines (not shown) are connected to the meter box 10 at building electrical contacts 26. The building power supply cables may be located in the housing chamber 15 by passing the power supply cables through openings 31 provided on side wall 19 as shown in FIG. 1.

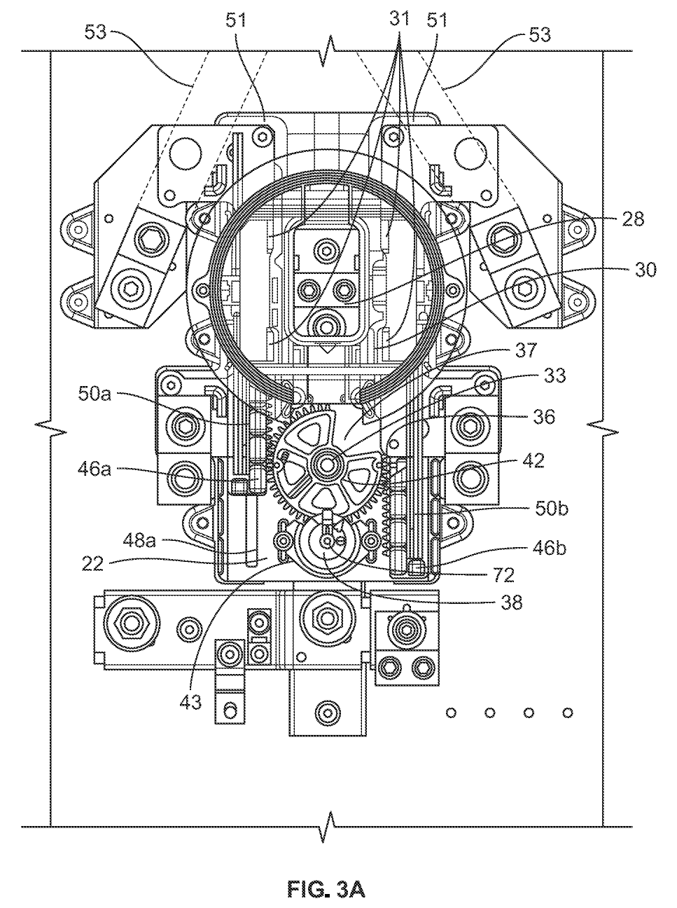

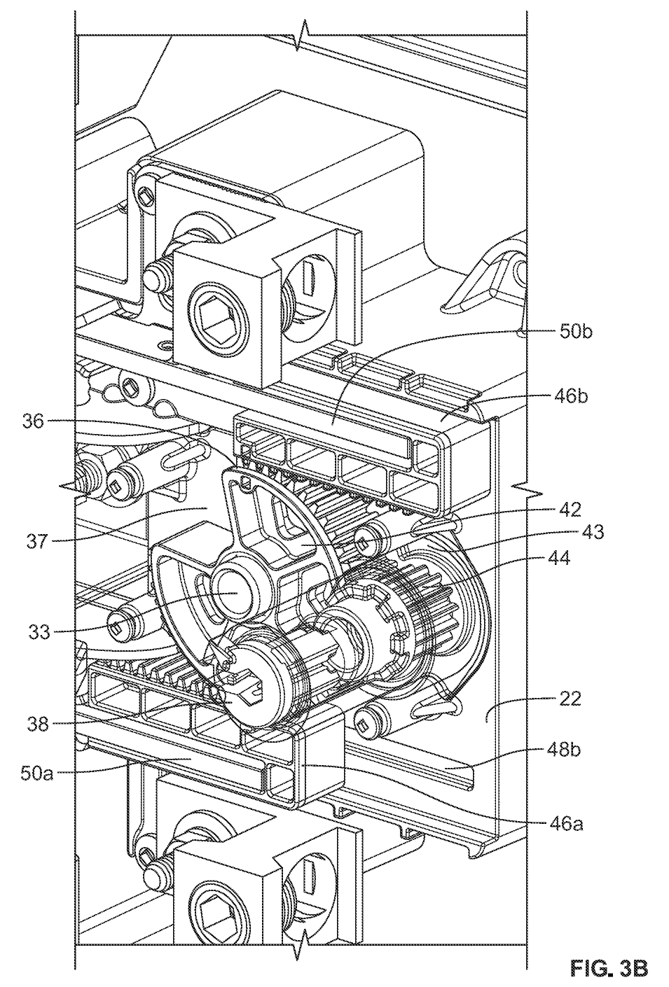

The base 22 includes a meter socket 28, which comprises a jumper plate 30. Jumper plate 30 includes a number of terminals 31 (see FIG. 3A) which are configured to receive a plurality of blade contacts (not shown) of the meter, such that the blade contacts abut contact surfaces of the meter socket 28 to form an electrical connection that serves to enable the supply of power to the meter. The meter may be a watt-meter, but other types of meters known in the art may also be used. Current is provided by an electrical grid and supplied to the service feed electrical contacts 24 through the power delivery cables, and continues through the meter socket 28 and meter. Power is ultimately delivered through the building electrical contacts 26 and building cables to a breaker box or main building breaker panel. The described flow of electricity is enabled when the meter is installed in the meter box 10 at the meter socket 28. A circuit is completed with a neutral connection (not shown) between the breaker box/main breaker panel and the meter box 10 at the neutral contacts 32, and with a second neutral connection (not shown) between the neutral contacts 32 and the electrical grid. The connection between the neutral contacts 32 and the electrical grid is provided using an additional cable. The neutral contacts 32 are shown in FIG. 2.

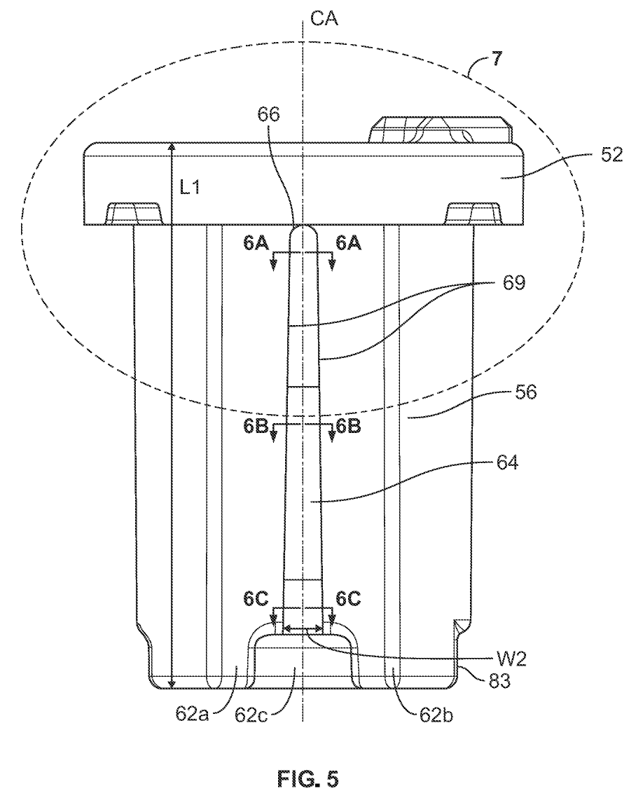

A meter box bypass mechanism 36 shown in FIG. 3A and 3B is provided in housing chamber 15. The bypass mechanism provides a mechanical means of creating a bypass in the circuit, as described below. The bypass in the circuit enables the meter to be removed from the meter socket specifically without producing an arc flash. As shown in FIG. 3B, an insert 38 is passed through an opening in a base cover 34, and seated in a hollow shaft 40. The hollow shaft 40 that includes a driving gear 44 that is rotatable relative to the hollow shaft 40. The hollow shaft 40 is fixed to a shaft base 43 which in turn is fixed to the housing base 22 by conventional means such as threaded fasteners. The teeth of the driving gear 44 mesh with a central gear 42 of meter box bypass mechanism 36. When seated in the hollow shaft, movement of the insert 38 is limited by the hollow shaft 40 to rotational movement of the insert about the insert central axis CA, shown in FIG. 5. Rotation of the insert causes the driving gear to rotate. The insert 38 is used to activate or deactivate, the bypass mechanism 36, and the interaction between the insert and bypass mechanism will be described in greater detail below.

FIG. 3A shows a front view of the base 22 with the base cover 34 removed such that the bypass mechanism 36 can be viewed in greater detail. The bypass mechanism 36 includes a central gear 42. The central gear 42 is seated on a central hub 33 which is fixed to the housing base 22. The central gear has a semicircular configuration with the teeth along the semicircular portion of the central gear circumference. As shown in FIG. 3A, a gap 37 is formed between the ends of the central gear semi-circular circumference. The teeth of the central gear 42 mesh with corresponding teeth the driving gear 44. The insert 38 is configured to connect to driving gear 44, such that a torque applied to the insert 38 rotates the driving gear 44, and thus also rotates the central gear 42. The central gear 42 is configured to drive two linear guides 46a, 46b, which are mounted within tracks 48a, 48b (48b not shown) of the main base 22. The rotational displacement of central gear 42 initiated by rotation of the insert 38 and driving gear 44 results in linear motion of the two linear guides 46a, 46b, which move linearly opposite each other (i.e. when the central gear 42 rotates clockwise, the left linear guide 46a moves linearly upward, toward meter socket 28 with respect to the central gear 42, while the right linear guide 46b moves linearly downward away from the meter socket 28) along their respective tracks 48a, 48b. The bypass mechanism 36 is in an engaged position when the left linear guide 46a is in a maximum lower position, farthest from the meter socket as enabled by track 48a, while the right linear guide 46b is in a maximum upper position, closest to the meter socket as enabled by track 48b. The bypass mechanism 36 is in a disengaged position when the left linear guide 46a is in a maximum upper position, proximate the meter socket 28 as enabled by track 48a, while the right linear guide 46b is in a maximum lower position, farthest from the meter socket 28 as enabled by track 48b. The bypass mechanism 36 is adjustably moveable between the two positions using the insert 38.

Each linear guide 46a, 46b includes a conductor plate 50a, 50b. The conductor plates 50a, 50b are configured such that when the bypass mechanism 36 is in the engaged position, the conductor plates 50a, 50b make contact with the contact surfaces of meter socket 28 such that a low resistance electrical path is provided between the service feed electrical contacts 24 and the building electrical contacts 26. In the event that the meter needs to be removed, the bypass mechanism 36 can be placed in the engaged position, which creates a second circuit which bypasses the meter due to the meter exhibiting a higher resistance than the conductor plates 50a, 50b. If the meter is removed, arc flashing will not occur between the blade contacts of the meter and the contact surfaces of meter socket 28 if the meter has been bypassed.

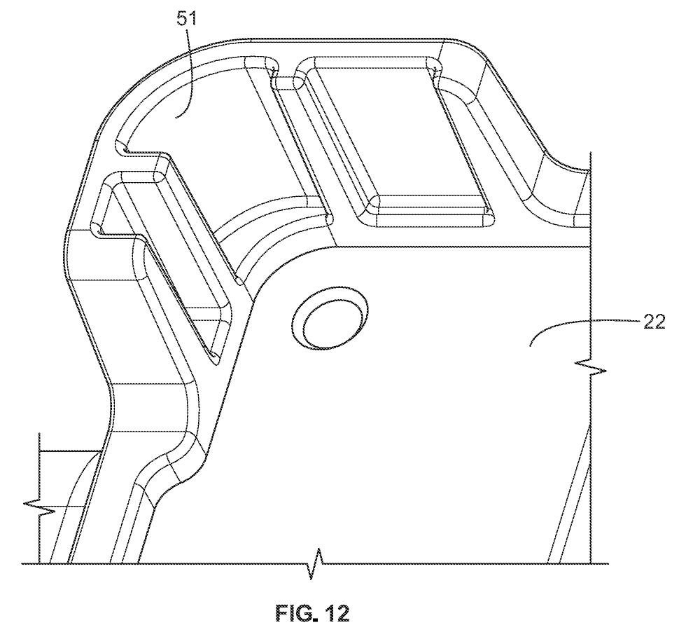

The meter socket 28 is equipped with plungers (not shown), which lock the linear guides 46a, 46b in place while a meter is not installed by clamping down on the linear guides 46a, 46b. The plungers ensure that the circuit is not unintentionally opened by disengaging the bypass mechanism 36 while a meter is not installed. When a meter is installed, the plungers are compressed, which releases the clamp and allows the bypass mechanism 36 to be actuated to the disengaged position. When the bypass mechanism 36 is in the engaged position, the right linear guide 46b may extend past the meter socket 28, resulting in a scenario where a cable (not shown) extending at an angle from service feed electrical contacts 24 could come in contact with the right linear guide 46b and unintentionally force the linear guide out of the plunger-induced lock. To eliminate such undesirable contact, a shoulder 51 is provided on the base 22 in a location along the base that limits the displacement of cables that may yield undesired contact between the cable and meter box components. The cables paths 53 are represented in dashed font in FIG. 3A. The semi-circular shoulder 51 is shown in the detailed view of FIG. 12. The shoulder extends upward from the base 22 into chamber 15. Note that the meter box 10 may include any number of similarly configured shoulders 51 required to prevent undesired contact between the cables and meter box components. Two shoulders are specifically represented in FIG. 3A. The shoulders 51 serve to minimize the contact between the linear guides 46a, 46b.

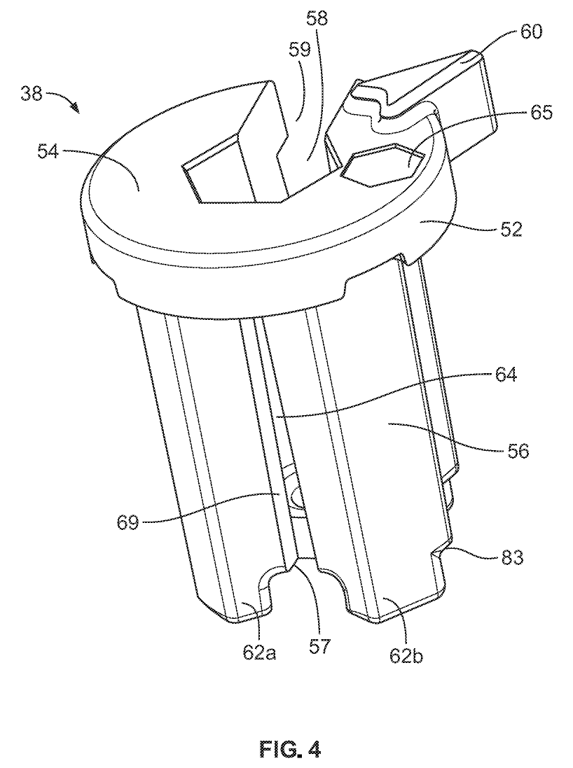

FIGS. 4-9 illustrate the insert 38 of the present disclosure. According to an exemplary embodiment, the insert 38 is made of zinc or zinc alloy cast in a mold,. Those skilled in the art will appreciate that other methods of manufacture and other materials could result in an equivalent piece.

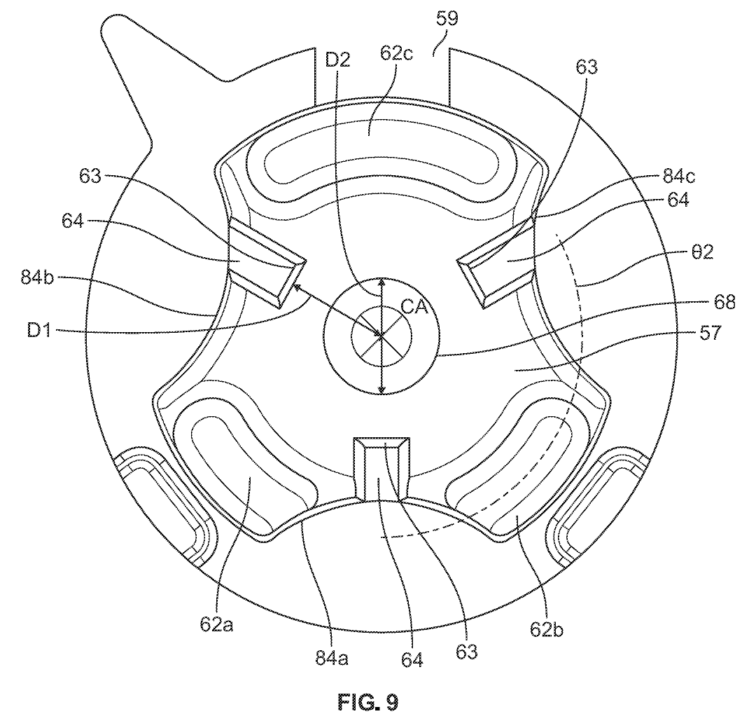

The insert 38 of the present disclosure prevents meter box users from applying a bypass mechanism actuating force at a magnitude that would damage meter box components such as central gear 42. The insert 38 comprises a unitary body 80. The unitary body 80 is further comprised of a head 52 and a hub 56. The head 52 and hub 56 are aligned longitudinally along central axis CA, shown in FIG. 5. The head 52 further comprises an upper face 54. The hub 56 has a hollow cylindrical wall that defines a hub interior 82. The hub extends from the head and terminates at the free hub end 83. A base 57 is located in the hub interior and spaced a longitudinal distance from hub end 83. A number of U-shaped openings 84a, 84b and 84c are formed in the hub at the free hub end 83. A U-shaped opening separates adjacent protuberances 62a, 62b, 62c located at the free hub end 83. See FIG. 9. Opening 84a is located between protuberances 62a, 62b. Opening 84b is located between protuberances 62a and 62c. Opening 84c is located between protuberance 62c and 62b. The protuberances are arcuate and configured to engage or otherwise interface with the driving gear 44. The driving gear includes a series of depressions (not shown) the gear and the depressions receive one or more of the protuberances to move the driving gear when the insert is rotated about axis CA.

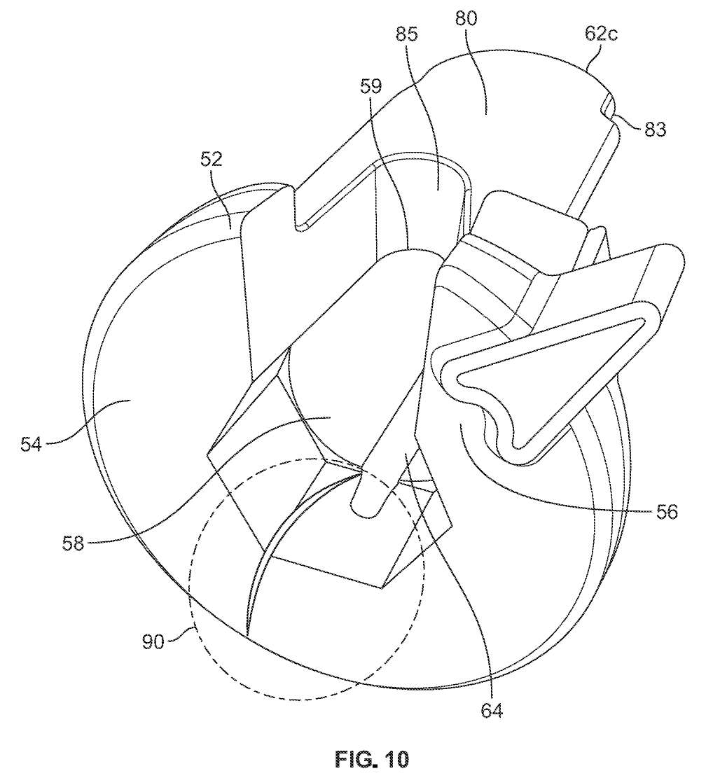

When the insert is located in the hollow shaft 40, a fastener is passed through base 57 and tightened to the driving gear 44 to maintain the insert in the shaft. The base 57 is best shown in FIG. 9. A faceted bore 58 extends through the head 54, and terminates in the upper portion of hub 56 proximate the head. As shown in FIG. 4, the faceted opening 58 includes five surfaces 61. Any number of surfaces may be provided in in the opening 58 in order to enable the insert to effectively minimize damage to meter box components as will be described herein. The bore 58 is configured to receive a tool for providing a torque to the insert 38, such as a hex key or wrench. Those skilled in the art will appreciate that the bore 58 can be configured to receive any type of tool for providing a torque, without departing from the scope of the present disclosure. In the exemplary embodiments shown, the bore 58 is configured with a hexagonal profile configured to accept a hex key. The hex arrangement of bore 58 only includes five surfaces, as a result, the bore 58 is not fully closed. The bore 58 is in communication with radially extending channel 59. The channel 59 extends radially between the bore 58 and an outer periphery of the head 52, and extends longitudinally relative to axis CA through the head 52. As shown in FIG. 10, the channel 59 is in communication with a V-shaped opening 85 formed along the wall of the hub 56 of body 80. The channel 59 and V-shaped opening 85 are in longitudinal communication to form an opening comprised of the channel and V-shaped opening.

Further provided is a directional indicator 60, which extends radially outwardly from the outer periphery of the head 52. The indicator 60 has a triangular shape and provides meter box users with a visual indication of the extent and direction of rotation of the insert. An indicia 65 may be provided in the front face 54 of the head 52. The indicia may provide guidance to the user regarding the size of the tool which the bore 58 is configured to accept to effectively rotate the insert.

The hub 56 includes a plurality of longitudinally extending breakline grooves 64. Each of the breakline groves 64 extends radially through the hub 56 as well as longitudinally along the length of the hub 56. As a result, the breakline grooves define slots through the hub 56. In the present disclosure, the hub 56 includes three breakline grooves, however any number of breakline grooves may be provided to enable the insert 38 to effectively prevent the application of excessive force to the bypass mechanism 36 and meter box 10. The breakline grooves 64 are similarly shaped and configured. The breakline grooves 64 are equally spaced about central axis CA along the hub 56 and each breakline groove is separated from each adjacent breakline groove by 120 degrees, shown in FIG. 9 as θ2. Because the breakline grooves 64 comprise substantially the same structure, as the description proceeds the structure of one breakline groove will be described and the description of the breakline groove structure applies to each of the plurality of breakline grooves 64.

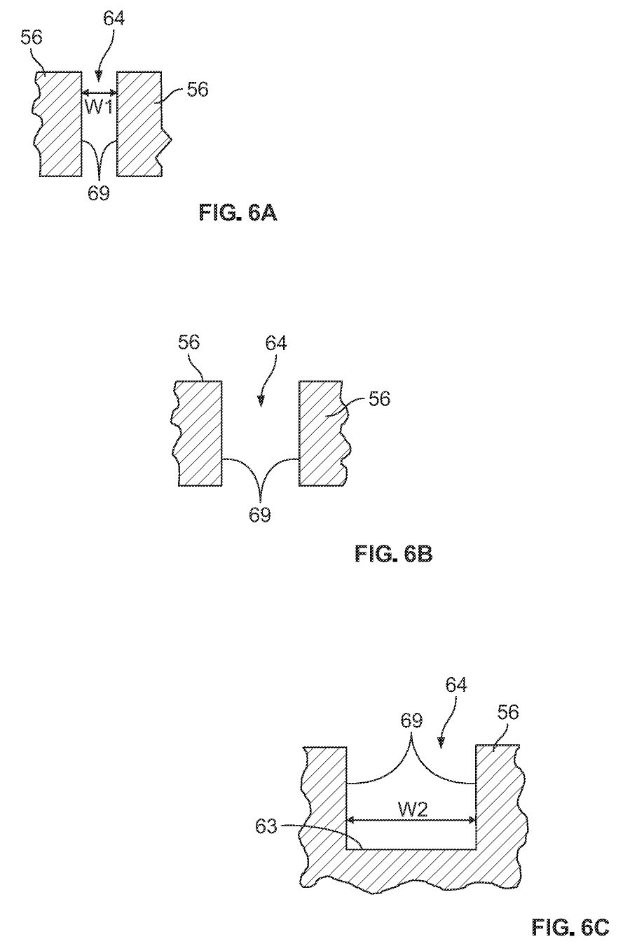

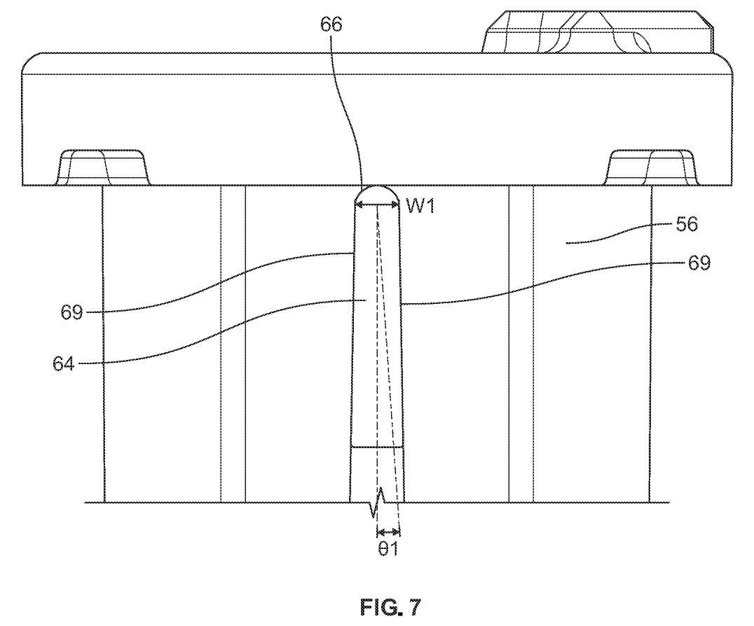

As shown in FIGS. 5 and 7 the breakline groove 64 has a closed, arcuate shaped end 66 proximate the head 52. The breakline groove 64 extends longitudinally, in the direction generally defined by axis CA and away from the closed end 66 toward base 57. The breakline groove terminates at base 57 at an open end 67. The open end is located at the base and is in communication with an associated opening 84a, or 84b or 84c. The breakline grooves are defined longitudinally by laterally opposed breakline groove walls 69. The distance separating the longitudinal breakline groove walls 69 varies as the groove extends longitudinally. See FIGS. 6A-6C represent sectional views of the breakline groove proximate the closed end 66, open end 67 near base 57, and in the location between the closed end 66 and open end 67. See also the locations of the sectional views as presented in FIG. 5. The circumferential/lateral distance separating the breakline groove walls is at a minimum magnitude nearest the closed end 66, shown as W1, and the circumferential/lateral distance is at a maximum magnitude nearest base 57 and at open end 67. See FIGS. 6A and 6C respectively. The distance separating the breakline groove walls 69 at a location between the closed end 66 and the base 57 has a magnitude between the magnitudes of the distances separating the walls at the closed end 66 and base 57. As a result, the breakline groove tapers outwardly according to angle θ1 as the breakline groove extends from the closed end 66 to the base 57 and open end 67. See FIG. 7. Each breakline groove terminates between adjacent protuberances 62a, 62b or 62c at base 57. As shown in FIG. 9, each breakline groove 64 forms an edge 63 along base 57. In the present embodiment, the distance W3 between each edge 63 and the tangent to insert hole 68 is 0.076 inches. The distance between the edge 63 and the central axis CA is shown as D1 (see FIG. 9), which in the present embodiment is 0.176 inches.

The breakline grooves 64 may generally have the following dimensions and dimensional relationships, however it should be understood that the breakline grooves may have any dimensions required to enable the insert to eliminate over torque of the bypass mechanism. The distance separating the longitudinal breakline groove walls 69 at the minimum magnitude W1 is 0.062 inches. This distance is shown in FIG. 7. The lateral/circumferential distance separating the longitudinal breakline walls at the maximum magnitude W2 is 0.094 inches. The distance W2 is shown in FIG. 5. The longitudinal breakline groove walls 69 taper laterally and diverge as the breakline grooves extend from the closed end 66 along central longitudinal axis CA from the minimum magnitude to the maximum magnitude at the angle θ1 of approximately 2 degrees. The overall length of the insert hub 56 including protuberances 62a, 62b, and 62c is 1.062 inches, shown as L1 in FIG. 5. The closed end 66 has a radius of 0.031 inches, but other radius values may be used. This foregoing configuration results in an increasing width of the breakline groove 64 as it extends longitudinally from the closed end 66 along the hub 56.

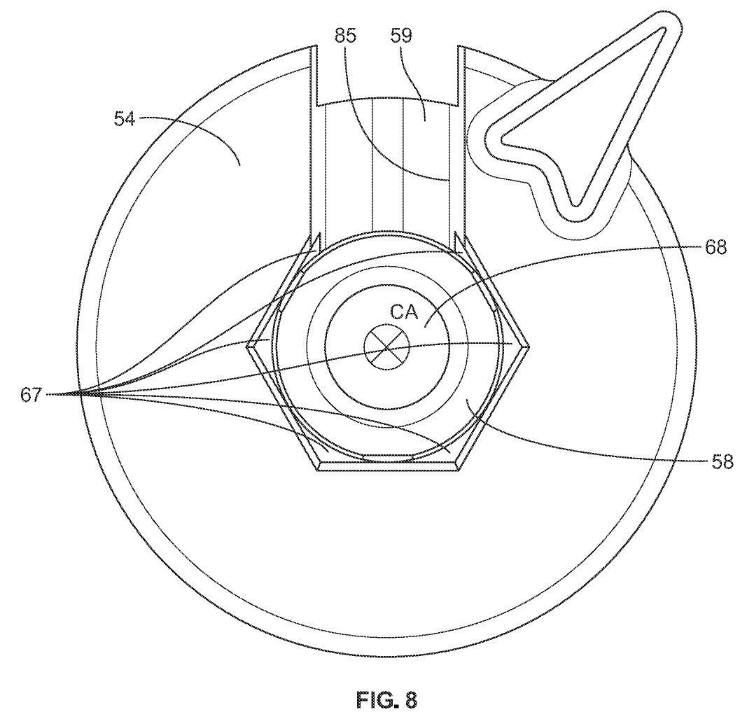

Referring to FIG. 8, a series of ribs 67 are positioned within the bore 58. The ribs 67 are offset longitudinally and below the upper face 54 and within the bore 58. The ribs are characterized by arcuate segments of material which span between adjacent surfaces 61 of the bore 58. The ribs 67 both reinforce the segments of the hub 56 between the breakline grooves 64, and serve as an abutment surface for the tool. As an abutment surface, the ribs serve to properly locate the tool such as a hex wrench at the desired longitudinal position in the bore. The ribs impeded the longitudinal movement of the tool through the bore, thereby positioning the tool in the desired bore location.

Referring to FIG. 9, the rear face 57 has an insert hole 68 which is configured to receive a fastener. The insert hole 68 has a diameter D2, which in the present embodiment may be about 0.2 inches. The insert hole 68 is configured to align with a receiving hole 70 (see FIG. 3B) of the driving gear 44 when the protuberances 62a, 62b, and 62c interface with the depressions of driving gear 44. When aligned, a fastener 72 (see FIG. 3A) can be inserted into the insert hole 68 and the receiving hole 70 so as to securely attach the insert 38 to the driving gear 44. Those skilled in the art will appreciate that the fastener 72 may be a screw, bolt, or other similar type of fastener. With the fastener installed, the insert 38 and the driving gear 44 rotate in unison when actuated with a tool.

In additional embodiments of the insert 38, the breakline grooves 64 may extend longitudinally from the head 52. The breakline grooves 64 may be designed without the semicircular closed end 66, instead either having a triangular-shaped profile extending from an apex, or having a profile where the walls of the breakline groove 64 are extended forward to the intersection between the head 52 and the hub 56, resulting in a linear front edge. A further additional embodiment may include two breakline grooves 64.

Referring to FIG. 10, an insert 38 which has undergone fracture is shown. The breakline grooves 64 are dimensioned and positioned to enable the insert 38 to fractures after a torque exceeding a predetermined threshold torque value is applied to the insert, for example, 225 ft.lbs of torque. This threshold torque is at a magnitude that produces a fracture 100 in the insert 38 and as a result prevents damage to the bypass mechanism 36 components or other components of the meter box 10. As seen in FIG. 10, the fracture 100 extends from a breakline groove 64 to the front face 54 (see dashed oval 90) of the head 52. The fracture is located between adjacent longitudinally extending breakline grooves 64. The fracture may extend completely through head 52. Independent of the extent of the fracture through the head, the fracture causes the bore 58 to change shape in a manner that prevents the bore 58 from receiving a tool to apply further torque to the insert. The opening comprised of the channel 59 and V-shaped opening 85 enables the change in the shape of the bore 58. As a result, no additional torque can be introduced to the system using the tool. In that manner, the insert 38 is designed as a ‘sacrificial component’ of the bypass mechanism 36, in that the less expensive insert component breaks to protects more complex parts, for example the central gear 42, from undesirable amounts of load. After a fracture occurs, the fractured insert is removed and replaced with a new insert. The specific manner and location of the fracture is dependent on the arrangement of the bore 58, the breakline grooves 64, the ribs 67, and the presence of the upper bore channel segment 59 and opening 85. The insert is intended to be easily replaceable, as installation requires only one fastener as discussed above.

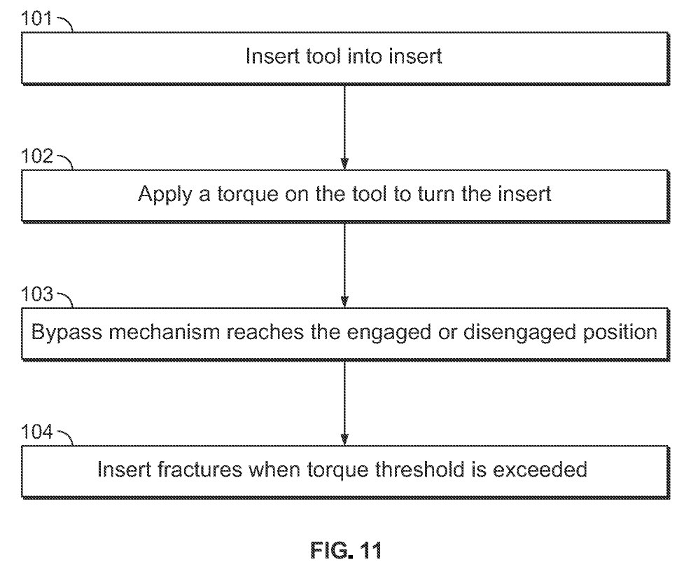

Referring to FIG. 11, a method of use of the insert 38 which results in fracture is shown. First, at 101, a tool is inserted into the insert 38. At 102, a torque is applied to the insert 38 using the tool, which results in rotational motion of the insert 38 and ensuing motion linear motion of the linear guides 46a, 46b in the bypass mechanism 36. At 103, once the bypass mechanism 36 reaches the engaged or disengaged position, the components of the bypass mechanism 36 will no longer move if additional torque is applied. At 104, if additional torque is applied, the insert fractures when the threshold is exceeded, which occurs before other components of the bypass mechanism 36 would break under excessive load.

As used herein, an element or step recited in the singular and proceeded with the word “a” or “an” should be understood as not excluding plural elements or steps unless such exclusion is explicitly recited. Furthermore, references to “one embodiment” of the disclosure or an “exemplary” or “example” embodiment are not intended to be interpreted as excluding the existence of additional embodiments that also incorporate the recited features. Likewise, limitations associated with “one embodiment” or “an embodiment” should not be interpreted as limiting to all embodiments unless explicitly recited.

Disjunctive language such as the phrase “at least one of X, Y, or Z,” unless specifically stated otherwise, is generally intended, within the context presented, to disclose that an item, term, etc. may be either X, Y, or Z, or any combination thereof (e.g., X, Y, and/or Z). Likewise, conjunctive language such as the phrase “at least one of X, Y, and Z,” unless specifically stated otherwise, is generally intended, within the context presented, to disclose at least one of X, at least one of Y, and at least one of Z.

The disclosed systems and methods are not limited to the specific embodiments described herein. Rather, components of the systems or steps of the methods may be utilized independently and separately from other described components or steps.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences from the literal language of the claims.

We claim:

1. An insert for actuating a bypass mechanism in a meter box, the insert comprising: a unitary body further comprising: a) a head, the head further comprising a bore, the bore being configured to receive a tool for applying a torque to the insert to enable or disable the meter box bypass mechanism; and b) a hub that defines an interior, the hub having a wall terminating at a hub end, the hub and body extending along a central axis, the hub further comprising a base located in the interior and a plurality of breakline grooves extending through the hub, each of the plurality of grooves extending in a direction aligned with the central axis from a location along the hub proximate the head to a location along the hub proximate the base.

2. The insert of claim 1, wherein each of the plurality of breakline grooves includes a closed end proximate the head and an open end proximate the base.

3. The insert of claim 2, wherein each breakline groove has opposed breakline groove walls separated by a lateral distance, the magnitude of the lateral distance separating the breakline groove walls being at a minimum near the closed end and the magnitude of the lateral distance separating the breakline groove walls being at a maximum proximate the base.

4. The insert of claim 1, wherein each breakline groove has opposed breakline groove walls separated by a lateral distance, the magnitude of the lateral distance separating the breakline groove walls being at a minimum proximate a first breakline groove end near the head and the magnitude of the lateral distance separating the breakline groove walls being at a maximum proximate the base.

5. The insert of claim 1, wherein the head comprises a channel that extends radially from the bore.

6. The insert of claim 5, wherein the hub includes an opening that is in communication with the channel.

7. The insert of claim 1, wherein the hub includes a plurality of openings provided at the hub end, the insert further comprising a plurality of protuberances at the hub end, each pair of adjacent protuberances being separated by an opening at the hub end.

8. The insert of claim 2, wherein the wherein the hub includes a plurality of openings provided at the hub end, the open end of each breakline groove being in communication with a respective opening at the hub end.

9. The insert of claim 1, wherein the insert comprises three breakline grooves.

10. The insert of claim 9, wherein the breakline grooves are spaced circumferentially about the hub such that the angle between adjacent grooves is about 120 degrees.

11. The insert of claim 1, wherein the closed end is arcuate.

12. The insert of claim 3 wherein the magnitude of the distance separating the breakline groove walls varies from about 0.031 inches to about 0.094 inches.

13. The insert of claim 1 wherein the bore comprises a number of surfaces, and a number of ribs, each rib extending between adjacent surfaces.

14. An insert for actuating a bypass mechanism in a meter box, the insert comprising: a unitary body further comprising:
a) a head, the head further comprising a bore, the bore being configured to receive a tool for applying a torque to the insert to enable or disable the meter box bypass mechanism, the head comprising a radially extending channel that extends through the head; and
b) a hub that defines an interior, the hub having a wall terminating at a hub end, the hub and body extending along a central axis, the hub further comprising an opening extending through the hub wall, the opening being in communication with the channel, the hub further comprising a base located in the interior, and a plurality of breakline grooves extending through the hub, each of the plurality of grooves having a closed end, an open end, and laterally opposed breakline groove walls extending between the open and closed ends, the breakline grooves extending in a direction aligned with the central axis, the closed end being located proximate the head and the open end located proximate the base.

15. The insert of claim 14, wherein each breakline groove has opposed breakline groove walls separated by a lateral distance, the magnitude of the lateral distance separating the breakline groove walls being at a minimum near the closed end of the breakline groove and the magnitude of the lateral distance separating the breakline groove walls being at a maximum proximate the open end of the breakline groove.

16. The insert of claim 15 wherein the insert is configured to produce a fracture when a torque of about 225 ft.lbs is applied to the insert.

17. The insert of claim 16 wherein the insert fracture is produced in at least the head.

18. A method for activating a bypass mechanism in a meter box, wherein the meter box comprises, a insert for actuating the bypass mechanism to enable the meter to be removed from the meter box, the insert comprising: a unitary body further comprising: a head, the head further comprising a bore, the bore being configured to receive a tool for applying a torque to the insert to enable the meter box bypass mechanism; and a hub that defines an interior, the hub having a wall terminating at a hub end, the hub and body extending along a central axis, the hub further comprising a base located in the interior and a plurality of breakline grooves extending through the hub, each of the plurality of grooves extending in a direction aligned with the central axis from a location along the hub proximate the head to a location along the hub proximate the base, the method comprising: applying a torque to rotate insert about the central axis, causing a fracture in the insert when the applied torque threshold is exceeded.

19. The method of claim 18 wherein the fracture is produced in the head.

20. The method of claim 18 wherein the head comprises a channel, and the hub includes an opening in the hub wall, the method further comprising changing the shape of the bore after the fracture is produced in the head, preventing a tool to be located in the bore.
